(19) United States
(12) Patent Application Publication
(10) Pub. No.: US 2009/0057828 A1
(43) Pub. Date: Mar. 5, 2009

(54) METAL-INSULATOR-METAL CAPACITOR AND METHOD FOR MANUFACTURING THE SAME

(76) Inventor: Myung-Il Kang, Yongin-si (KR)

Correspondence Address: SHERR & VAUGHN, PLLC, 620 HERNDON PARKWAY, SUITE 200, HERNDON, VA, 20170, US

(21) Appl. No.: 12/201,461

(22) Filed: Aug. 29, 2008

(30) Foreign Application Priority Data
Aug. 29, 2007 (KR) 10-20070087066

(51) Int. Cl. H01L 21/02; H01L 29/92

(52) U.S. Cl. 257/532; 438/396; 361/301.4; 257/E29.343; 257/E21.008

(57) ABSTRACT

A metal-insulator-metal (MIM) capacitor having fast frequency characteristics and a method for manufacturing the same are disclosed. The disclosed MIM capacitor may include a first intermetal insulating film, a lower metal layer formed over the first intermetal insulating film, a second intermetal insulating film formed around the lower metal layer, and a third intermetal insulating film formed over the lower metal layer. A first-capacitor lower metal layer, a first-capacitor insulating film, a first-capacitor upper metal layer, and a first capping layer may be sequentially formed over a portion of the third intermetal insulating film. A first interlayer insulating film, a fourth intermetal insulating film, and a second interlayer insulating film may be sequentially formed over the third intermetal insulating film including the first capping layer. A second-capacitor lower metal layer may extend through the second interlayer insulating film and the first capping layer such that the second-capacitor lower metal layer is connected to the first-capacitor upper metal layer. A first passivation film may be formed over the second-capacitor lower metal layer. A second-capacitor upper metal layer may be formed over a portion of the first passivation film and extending through the first passivation film in a region where the second-capacitor lower metal layer is arranged such that the second-capacitor upper metal layer is connected to the second-capacitor lower metal layer. Second to fourth passivation films may be sequentially formed over the first passivation film including the second-capacitor upper metal layer.

The present application claims priority under 35 U.S.C. 119 to Korean Patent Application No. 10-2007-0087066 (filed on Aug. 29, 2007), which is hereby incorporated by reference in its entirety.

### BACKGROUND

Recent high integration techniques for semiconductor devices led to research and development of a semiconductor device in which an analog capacitor is integrated with a logic circuit. Currently, this product is available. In the case of an analog capacitor used in a complementary metal oxide silicon (CMOS) logic, it may take the form of polysilicon-insulator-polysilicon (PIP) or metal-insulator-metal (MIM).

Such a PIP or MIM capacitor needs to be relatively accurately constructed, as compared to an MOS type capacitor or a junction capacitor, because it is independent of bias. In the case of a capacitor having a PIP structure, conductive polysilicon is used for upper and lower electrodes of the capacitor. For this reason, oxidation may occur at an interface between the electrodes and a dielectric thin film. A natural oxide film may be formed, reducing the total capacitance of the capacitor. Furthermore, a reduction in capacitance can occur due to a depletion region formed in the polysilicon layer. For these reasons, the PIP capacitor is unsuitable for high-speed and high-frequency operations.

To solve this problem, an MIM capacitor, in which both the upper and lower electrodes are formed using a metal layer, was proposed. Currently, the MIM capacitor may be used in high-performance semiconductor devices because it exhibits a low specific resistance, and does not exhibit a parasitic capacitance caused by an internal depletion.

However, related MIM capacitors have a relatively low capacity for the effective area they use. It may be possible to increase the capacitor value by increasing the capacitor area or by using a film having a high dielectric constant.

The method of increasing the capacitor area undesirably increases chip area. Also, the use of a film having a high dielectric constant requires additional investment in equipment, or a new process. Furthermore, where a large, lower capacitor copper pattern is formed, a dishing phenomenon may occur during a chemical mechanical polishing (CMP) process for copper lines. That is, the copper lines may be recessed. In this case, it may be practically impossible to obtain an accurate capacitance value. This may cause a degradation in the characteristics of the analog device, including a reduction in the leakage and breakdown voltages. Consequently, reliability becomes a problem.

### SUMMARY

Embodiments relate to a semiconductor device and a method for manufacturing the same, and more particularly, to a metal-insulator-metal (MIM) capacitor having fast frequency characteristics and a method for manufacturing the same. Embodiments relate to a metal-insulator-metal capacitor capable of achieving an enhancement in the reliability of a semiconductor device, and a method for manufacturing the same.

Embodiments relate to a metal-insulator-metal (MIM) capacitor which may include a first intermetal insulating film, a lower metal layer formed over the first intermetal insulating film, a second intermetal insulating film formed around the lower metal layer, and a third intermetal insulating film formed over the lower metal layer. A first-capacitor lower metal layer, a first-capacitor insulating film, a first-capacitor upper metal layer, and a first capping layer may be sequentially formed over a portion of the third intermetal insulating film. A first interlayer insulating film, a fourth intermetal insulating film, and a second interlayer insulating film may be sequentially formed over the third intermetal insulating film including the first capping layer. A second-capacitor lower metal layer may extend through the second interlayer insulating film and the first capping layer such that the second-capacitor lower metal layer is connected to the first-capacitor upper metal layer. A first passivation film may be formed over the second-capacitor lower metal layer. A second-capacitor upper metal layer may be formed over a portion of the first passivation film and extending through the first passivation film in a region where the second-capacitor lower metal layer is arranged such that the second-capacitor upper metal layer is connected to the second-capacitor lower metal layer. Second to fourth passivation films may be sequentially formed over the first passivation film including the second-capacitor upper metal layer.

Embodiments relate to a method for manufacturing a metal-insulator-metal (MIM) capacitor which includes: forming a first intermetal insulating film; forming a lower metal layer over the first intermetal insulating film; forming a second intermetal insulating film around the lower metal layer; forming a third intermetal insulating films over the lower metal layer; sequentially forming a first-capacitor lower metal layer, a first-capacitor insulating film, a first-capacitor upper metal layer, and a first capping layer over the third intermetal insulating film; forming a first interlayer insulating film, a fourth intermetal insulating film, and a second interlayer insulating film over the third intermetal insulating film including the first capping layer; forming a second-capacitor lower metal layer extending through the second interlayer insulating film and the first capping layer, and connecting to the first-capacitor upper metal layer; forming a first passivation film over the second-capacitor lower metal layer; forming a second-capacitor upper metal layer over a portion of the first passivation film such that the second-capacitor upper metal layer extends through the first passivation film in a region where the second-capacitor lower metal layer is arranged, such that the second-capacitor upper metal layer is connected to the second-capacitor lower metal layer; and sequentially forming second to fourth passivation films over the first passivation film including the second-capacitor upper metal layer.

### DRAWINGS

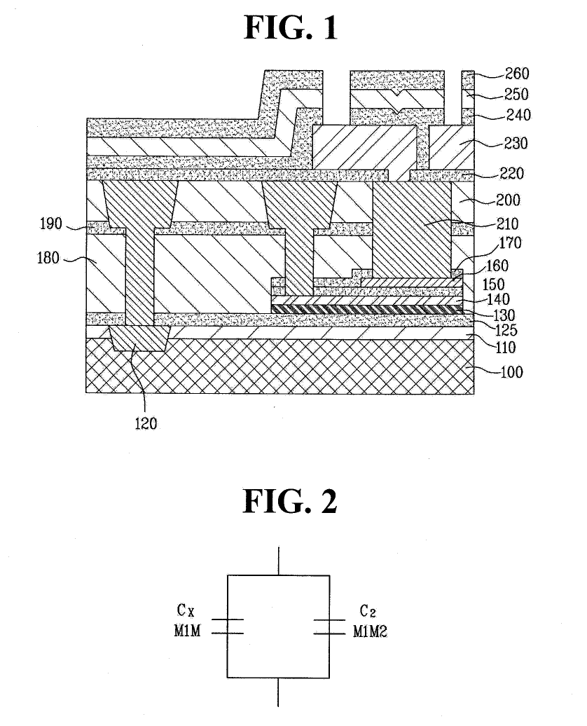

Example FIG. 1 is a view illustrating a metal-insulator-metal (MIM) capacitor according to embodiments.

Example FIG. 2 is an MIM capacitor having a parallel structure in accordance with embodiments.

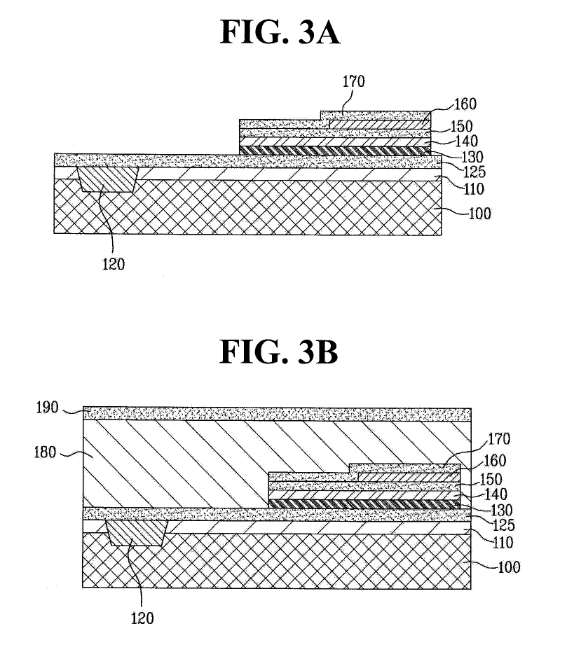

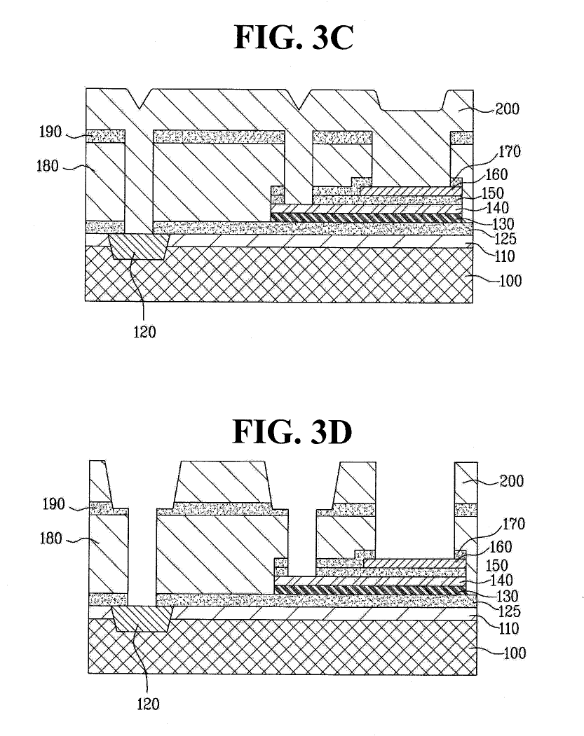

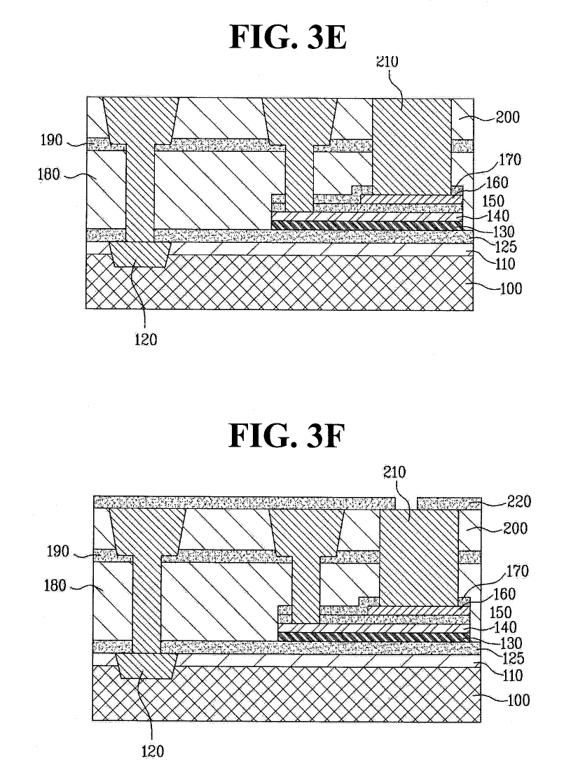

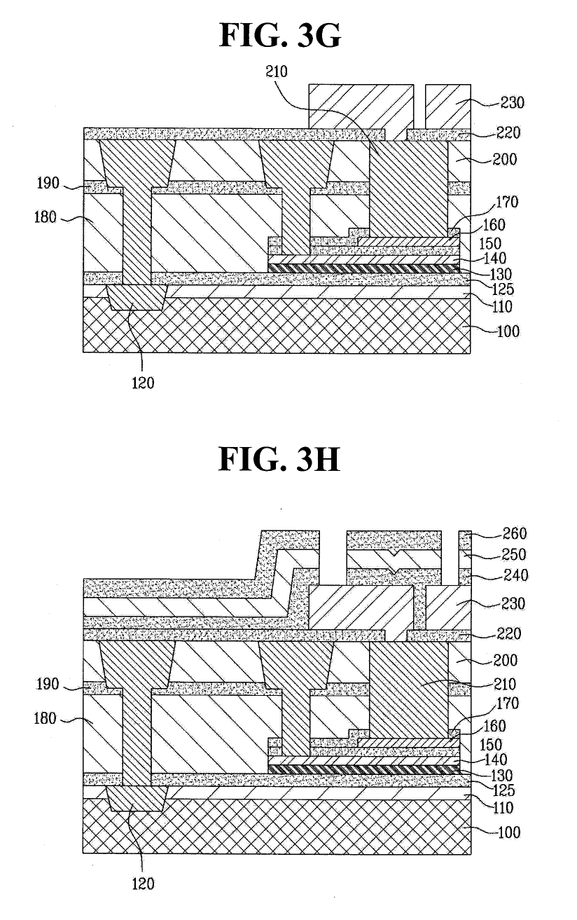

Example FIGS. 3A to 3H are views illustrating a method for manufacturing the MIM capacitor in accordance with embodiments.

### DESCRIPTION

Example FIG. 1 is a view illustrating a metal-insulator-metal (MIM) capacitor according to embodiments. As shown in example FIG. 1, the MIM capacitor according to embodiments may include a first intermetal insulating film 100, a second intermetal insulating film 110 formed over the first intermetal insulating film 100, a lower metal layer 120 formed in a portion of the second intermetal insulating film 110, and a third intermetal insulating film 125 formed over the second intermetal insulating film 110 including the lower metal layer 120. The MIM capacitor may also include a first-capacitor lower metal layer formed over a portion of the third intermetal insulating film 125. The first-capacitor lower metal layer may include two layers 130 and 140. The MIM capacitor may further include a first-capacitor insulating film 150 formed over the layer 140 of the first-capacitor lower metal layer, a first-capacitor upper metal layer 160 formed over a portion of the first-capacitor insulating film 150, a first capping layer 170 formed over the first-capacitor insulating film 150 including the first-capacitor upper metal layer 160, a first interlayer insulating film 180 formed over the third intermetal insulating film 125 including the first capping layer 170, a fourth intermetal insulating film 190 formed over the first interlayer insulating film 180, and a second interlayer insulating film 200 formed over the fourth intermetal insulating film 190.

The MIM capacitor may further include a second-capacitor lower metal layer 210 extending through the second interlayer insulating film 200 and first capping layer 170 such that the second-capacitor lower metal layer 210 is connected to the first-capacitor upper metal layer 160, a first passivation film 220 formed over the second-capacitor lower metal layer 210, and a second-capacitor upper metal layer 230 formed over a portion of the first passivation film 220. The second-capacitor upper metal layer 230 may extend through the first passivation film 220 in a region where the second-capacitor lower metal layer 210 is arranged such that the second-capacitor upper metal layer 230 is connected to the second-capacitor lower metal layer 210. Additionally, the MIM capacitor may include a second passivation film 240, a third passivation film 250, and a fourth passivation film 260, which are sequentially formed over the first passivation film 220 including the second-capacitor upper metal layer 230.

In the MIM capacitor according to embodiments, a first capacitor CX may be constituted by the first-capacitor lower metal layer, namely, the layers 130 and 140, the first-capacitor insulating film 150, and the first-capacitor upper metal layer 160. A second capacitor C2 may be constituted by the second-capacitor lower metal layer 210, the first passivation film 220, and the second-capacitor upper metal layer 220. The second capacitor C2 may be laminated over the first capacitor CX. Thus, two capacitor structures connected in parallel may be formed as shown in example FIG. 2. As a result, it is possible to obtain a capacitance of “CX+C2”. In accordance with these structures, embodiments can obtain an increased capacitance, namely, “CX+C2”, for the same area, without any mask addition.

Hereinafter, a method for manufacturing the MIM capacitor in accordance with embodiments will be described in detail. Example FIGS. 3A to 3H are views illustrating the MIM capacitor manufacturing method according to embodiments. The first and second intermetal insulating films 100 and 110 may be sequentially deposited over a semiconductor substrate, as shown in example FIG. 3A. The first and second intermetal insulating films 100 and 110 may be then etched in accordance with a dry etching process or a wet etching process, to form a trench. The lower metal layer 120 may then be formed in the trench. Thereafter, the third intermetal insulating film 125, the first-capacitor lower metal layer, namely, the layers 130 and 140, the first-capacitor insulating film 150, and the first-capacitor upper metal layer 160 may be sequentially deposited over the second intermetal insulating film 110 including the lower metal layer 120. The first-capacitor upper metal layer 160 may then be etched, to partially expose the first-capacitor insulating film 150.

Subsequently, the first capping layer 170 may be deposited over the entire upper surface of the semiconductor substrate including the first-capacitor upper metal layer 160. A mask pattern may be formed over the first capping layer 170 in accordance with an exposure and development process. Thereafter, the first-capacitor lower metal layer, namely, the layers 130 and 140, the first-capacitor insulating film 150, the first-capacitor upper metal layer 160, and the first capping layer 170 may be etched, using the mask pattern, in accordance with a dry etching process or a wet etching process, such that the third intermetal insulating film 125 is partially exposed. The mask pattern may then be removed.

The first intermetal insulating film 100 may be made of a fluorosilicate glass (FSG) oxide. The second intermetal insulating film 110 may be made of an SiH₄ oxide. The third intermetal insulating film 125 may be made of SiN. The first-capacitor lower metal layer, which includes the layers 130 and 140, may be made of Ti/TiN. The first-capacitor insulating film 150 may be made of SiN. The first-capacitor upper metal layer 160 may be made of TiN.

Thereafter, as shown in example FIG. 3B, the first interlayer insulating film 180 may be deposited over the entire upper surface of the semiconductor substrate including the first capping layer 170. To eliminate a step formed by the etched first-capacitor upper metal layer 160, the first interlayer insulating film 180 may be planarized in accordance with a chemical mechanical polishing (CMP) process. The fourth intermetal insulating film 190 may then be deposited over the first interlayer insulating film 180. The first interlayer insulating film 180 may be made of tetraethylorthosilicate (TEOS). The fourth intermetal insulating film 190 may be made of SiN.

Subsequently, as shown in example FIG. 3C, a contact hole extending through the third intermetal insulating film 125, first interlayer insulating film 180, and fourth intermetal insulating film 190 may be formed in accordance with a dry etching process or a wet etching process, using a contact hole mask pattern formed in accordance with an exposure and development process. Similarly, a contact hole extending through the first-capacitor insulating film 150, first capping layer 170, first interlayer insulating film 180, and fourth intermetal insulating film 190, and a contact hole extending through the first capping layer 170, first interlayer insulating film 180, and fourth intermetal insulating film 190 may also be formed. The second interlayer insulating film 200 may then be deposited over the entire upper surface of the semiconductor substrate including the contact holes. The second interlayer insulating film 200 may be made of TEOS.

Thereafter, as shown in example FIG. 3D, desired portions of the fourth intermetal insulating film 190 and the second interlayer insulating film 200 may be etched in accordance with a dry etching process or a wet etching process, using a metal mask pattern formed in accordance with an exposure and development process, to form contact holes corresponding to the contact holes formed in the process shown in example FIG. 3C. In these contact holes, an upper metal layer and the second-capacitor lower metal layer 210 may be formed. The fourth intermetal insulating film 190, which may be arranged as an intermediate layer, may have an etch selectivity different from that of the second interlayer insulating film 200. As a result, a dual damascene structure may be formed. Since the metal mask may be the same size as the contact hole mask in a region corresponding to the contact hole, in which the second-capacitor lower metal layer 210 will be formed, the second interlayer insulating film 200 and fourth intermetal insulating film 190 may be etched such that the contact hole has a vertical side wall having no step.

Subsequently, as shown in example FIG. 3E, a metal such as copper may be deposited over the entire upper surface of the semiconductor substrate including the contact holes. The deposited metal may then be planarized in accordance with a CMP process.

Thereafter, as shown in example FIG. 3F, the first passivation film 220 may be deposited over the second interlayer insulating film 200, in order to protect the second-capacitor lower metal layer 210. The first passivation film 220 may be made of SiN. To form the second-capacitor upper metal layer 230, together with a pad, the first passivation film 220 may be partially etched in a region where the second-capacitor lower metal layer 210 is arranged, in accordance with a dry etching process or a wet etching process, using a mask pattern formed in accordance with an exposure and development process.

As shown in example FIG. 3G, aluminum (Al) may then be deposited to form the pad. The deposited aluminum may subsequently be etched in accordance with a dry etching process or a wet etching process, using a mask pattern formed in accordance with an exposure and development process. The deposited aluminum may be divided into a first portion which will be used as the pad, and a second portion which will be used as the second-capacitor upper metal layer 230.

Thereafter, as shown in example FIG. 3H, the second passivation film 240, the third passivation film 250, and the fourth passivation film 260 may be sequentially deposited over the entire upper surface of the semiconductor substrate including the pad and second-capacitor upper metal layer 230, to protect the semiconductor device. Subsequently, the second passivation film 240, third passivation film 250, and fourth passivation film 260 may be etched to partially expose the second-capacitor upper metal layer 230. As apparent from the above description, the MIM capacitor according to embodiments can obtain an increased capacitance for the same area, without any mask addition.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first intermetal insulating film;
a lower metal layer formed over the first intermetal insulating film;
a second intermetal insulating film formed around the lower metal layer;
a third intermetal insulating film formed over the lower metal layer;
a first-capacitor lower metal layer, a first-capacitor insulating film, a first-capacitor upper metal layer, and a first capping layer sequentially formed over a portion of the third intermetal insulating film;
a first interlayer insulating film, a fourth intermetal insulating film, and a second interlayer insulating film sequentially formed over the third intermetal insulating film including the first capping layer;
a second-capacitor lower metal layer extending through the second interlayer insulating film and the first capping layer such that the second-capacitor lower metal layer is connected to the first-capacitor upper metal layer;
a first passivation film formed over the second-capacitor lower metal layer;
a second-capacitor upper metal layer formed over a portion of the first passivation film and extending through the first passivation film in a region where the second-capacitor lower metal layer is arranged such that the second-capacitor upper metal layer is connected to the second-capacitor lower metal layer; and
second to fourth passivation films sequentially formed over the first passivation film including the second-capacitor upper metal layer.

2. The apparatus of claim 1, wherein the second-capacitor lower metal layer, the first passivation film, and the second-capacitor upper metal layer are laminated over a structure constituted by the first-capacitor lower metal layer, the first-capacitor insulating film, and the first-capacitor upper metal layer.

3. A method comprising:
forming a first intermetal insulating film;
forming a lower metal layer over the first intermetal insulating film;
forming a second intermetal insulating film around the lower metal layer;
forming a third intermetal insulating films over the lower metal layer;
sequentially forming a first-capacitor lower metal layer, a first-capacitor insulating film, a first-capacitor upper metal layer, and a first capping layer over the third intermetal insulating film;
forming a first interlayer insulating film, a fourth intermetal insulating film, and a second interlayer insulating film over the third intermetal insulating film including the first capping layer;
forming a second-capacitor lower metal layer extending through the second interlayer insulating film and the first capping layer, and connecting to the first-capacitor upper metal layer;
forming a first passivation film over the second-capacitor lower metal layer;
forming a second-capacitor upper metal layer over a portion of the first passivation film such that the second-capacitor upper metal layer extends through the first passivation film in a region where the second-capacitor lower metal layer is arranged, such that the second-capacitor upper metal layer is connected to the second-capacitor lower metal layer; and
sequentially forming second to fourth passivation films over the first passivation film including the second-capacitor upper metal layer.

4. The method of claim 3, wherein forming the first interlayer insulating film, the fourth intermetal insulating film, and the second interlayer insulating film over the third intermetal insulating film including the first capping layer comprises:
depositing the first interlayer insulating film over an entire upper surface of the third intermetal insulating film, and planarizing the first interlayer insulating film in accordance with a chemical mechanical polishing process;
forming the fourth intermetal insulating film over the first interlayer insulating film;
forming a contact hole extending through the first capping layer, the first interlayer insulating film, and fourth intermetal insulating film, to partially expose the first-capacitor upper metal layer;
forming the second interlayer insulating film over an entire upper surface of the resulting structure including the contact hole; and
etching the fourth intermetal insulating film and the second interlayer insulating film in a region corresponding to the contact hole.

5. The method of claim 4, wherein forming a second-capacitor upper metal layer over a portion of the first passivation film such that the second-capacitor upper metal layer extends through the first passivation film in a region where the second-capacitor lower metal layer is arranged, such that the second-capacitor upper metal layer is connected to the second-capacitor lower metal layer comprises:
depositing copper over the entire upper surface of the resulting structure after forming the first interlayer insulating film, the fourth intermetal insulating film, and the second interlayer insulating film over the third intermetal insulating film including the first capping layer, to form the second-capacitor lower metal layer, and planarizing the formed second-capacitor lower metal layer in accordance with a chemical mechanical polishing process.

6. The method of claim 3, wherein forming a second-capacitor upper metal layer over a portion of the first passivation film such that the second-capacitor upper metal layer extends through the first passivation film in a region where the second-capacitor lower metal layer is arranged, such that the second-capacitor upper metal layer is connected to the second-capacitor lower metal layer comprises:
partially etching the first passivation film in a region where the second-capacitor lower metal layer is arranged;
depositing aluminum over the first passivation film, and etching the deposited aluminum such that the deposited aluminum is divided into a first portion, which will be used as a pad, and a second portion, which will be used as the second-capacitor upper metal layer.

7. The method of claim 3, wherein the step of sequentially forming the first-capacitor lower metal layer, the first-capacitor insulating film, the first-capacitor upper metal layer, and the first capping layer over the third intermetal insulating film further comprises:
etching the first-capacitor lower metal layer, the first-capacitor insulating film, the first-capacitor upper metal layer, and the first capping layer such that the third intermetal insulating film is partially exposed.

8. The method of claim 3, wherein the first intermetal insulating film is made of a fluorosilicate glass oxide.

9. The method of claim 3, wherein the third intermetal insulating film is made of SiN.

10. The method of claim 3, wherein the first interlayer insulating film is made of tetraethylorthosilicate.

11. The method of claim 4, wherein the step of forming the contact hole extending through the first capping layer, the first interlayer insulating film, and fourth intermetal insulating film, to partially expose the first-capacitor upper metal layer, comprises:
forming a contact hole extending through the first-capacitor insulating film, the first capping layer film, the first interlayer insulating film, and the fourth intermetal insulating film; and
forming a contact hole extending through the third intermetal insulating film, the first interlayer insulating film, and the fourth intermetal insulating film in accordance with an etching process using a contact hole mask pattern.

12. The method of claim 4, wherein the contact hole extending through the first capping layer, the first interlayer insulating film, and fourth intermetal insulating film, to partially expose the first-capacitor upper metal layer, is etched to have a vertical side wall having no step.

13. The method of claim 4, wherein the fourth intermetal insulating film has a dual damascene structure in a contact hole region other than a contact hole where the second-capacitor lower metal layer will be formed.

14. The method of claim 3, wherein the first-capacitor lower metal layer, the first-capacitor insulating film, and the first-capacitor upper metal layer constitute a first capacitor, and the second-capacitor lower metal layer, the first passivation film, and the second-capacitor upper metal layer constitute a second capacitor, to form a parallel structure, in which the first and second capacitors are connected in parallel.

15. The apparatus of claim 1, wherein the first-capacitor lower metal layer, the first-capacitor insulating film, and the first-capacitor upper metal layer constitute a first capacitor, and the second-capacitor lower metal layer, the first passivation film, and the second-capacitor upper metal layer constitute a second capacitor, to form a parallel structure, in which the first and second capacitors are connected in parallel.

16. The method of claim 3, wherein the second intermetal insulating film is made of an SiH₄ oxide.

17. The method of claim 3, wherein the first-capacitor lower metal layer is made of Ti/TiN.

18. The method of claim 3, wherein the first-capacitor insulating film is made of SiN.

19. The method of claim 3, wherein the first-capacitor upper metal layer is made of TiN.

20. The method of claim 3, wherein the fourth intermetal insulating film is made of SiN.
